(19) United States
(12) Patent Application Publication
(10) Pub. No.: US 2024/0186101 A1
(43) Pub. Date: Jun. 6, 2024

(54) VAPORIZER, ION SOURCE, ION BEAM IRRADIATION APPARATUS, AND AN OPERATING METHOD FOR A VAPORIZER

(71) Applicant: NISSIN ION EQUIPMENT CO., LTD., Koka-city (JP)

(72) Inventors: Yuya HIRAI, Koka-City (JP); Yuta IWANAMI, Koka-City (JP); Suguru ITOI, Koka-City (JP); Weijiang ZHAO, Koka-City (JP)

(73) Assignee: NISSIN ION EQUIPMENT CO., LTD., Koka-City (JP)

(21) Appl. No.: 18/366,842

(22) Filed: Aug. 8, 2023

(30) Foreign Application Priority Data
Dec. 2, 2022 (JP) 2022-193211

(51) Int. Cl. H01J 37/08; H01J 37/18

(52) U.S. Cl. CPC H01J 37/08; H01J 37/18; H01J 2237/006; H01J 2237/186

(57) ABSTRACT

An vaporizer includes a crucible, a heater that heats the crucible, a support member that supports the crucible and includes an internal space in which a pressure in the internal space can be changed, and a control device. The control device increases the pressure of the internal space when the heating of the crucible by the heater is stopped, compared to the pressure when the crucible is heated by the heater.

### CROSS-REFERENCE TO RELATED APPLICATION

This Application is based on and claims priority to Japanese Application No. 2022-193211, filed on Dec. 2, 2022, in the Japan Patent Office, the contents of which being incorporated by reference herein in its entirety.

### BACKGROUND

In an ion source, an ion beam may be extracted from a plasma generated from a vapor.

The vapor may be produced by heating a solid material. When solid material becomes equal to or higher than a sublimation temperature of the solid material, the vapor is generated.

In order to continuously generate a plasma, a stable supply of a vapor is required. In order to stably supply a vapor, it is necessary to stably control the temperature of the solid material.

### SUMMARY

It is an aspect to make it possible to stably control a temperature of the solid material.

According to an aspect of one or more embodiments, there is provided an vaporizer comprising a crucible, a heater that heats the crucible, a support member that supports the crucible and includes an internal space in which a pressure in the internal space can be changed; and a control device configured to increase the pressure of the internal space when the heating of the crucible by the heater is stopped, compared to the pressure when the crucible is heated by the heater.

According to another aspect of one or more embodiments, there is provided an operating method for a vaporizer comprising a crucible, a heater that heats the crucible, a support member that supports the crucible and includes an internal space in which a pressure in the internal space can be changed, the operating method comprising operating the vaporizer in which the pressure of the internal space is increased when the heating of the crucible by the heater is stopped compared to the pressure when the crucible is heated by the heater.

According to yet another aspect of one or more embodiments, there is provided a vaporizer comprising a crucible; a heater configured to heat the crucible; a support member that supports the crucible and includes an internal space; and a control device configured to control to, when the heater is turned off, increase a pressure of the internal space with respect to the pressure of the internal space when the heater is turned on.

### BRIEF DESCRIPTION OF THE DRAWINGS

The above and/or other aspects will become apparent and more readily appreciated from the following description of embodiments, taken in conjunction with the accompanying drawings, in which:

FIG. 1 is a schematic cross-sectional view of a vaporizer according to some embodiments;

FIG. 2 is a perspective view of a support member, according to some embodiments;

FIG. 3 illustrates an example of a flowchart of a method of operating a vaporizer, according to some embodiments;

FIG. 4 illustrates an example of a vaporizer, according to some embodiments;

FIG. 5 illustrates an example of a vaporizer, according to some embodiments;

FIG. 6 illustrates an example of a first bottom lid, according to some embodiments;

FIG. 7 illustrates an example of a second bottom lid, according to some embodiments;

FIG. 8 illustrates an example of a vaporizer, according to some embodiments;

FIG. 9 illustrates an example of a vaporizer, according to some embodiments;

FIG. 10 illustrates an example of a vaporizer, according to some embodiments;

FIG. 11 illustrates an example of a vaporizer, according to some embodiments;

FIG. 12 illustrates an example of an ion source provided with a vaporizer and an ion beam irradiation apparatus provided with the ion source, according to some embodiments.

### DETAILED DESCRIPTION

In an ion source, an ion beam may be extracted from a plasma generated in a plasma generation chamber. The plasma is generated by discharge of a gas introduced into the plasma generation chamber. However, when an appropriate gas is not available for plasma generation, a vapor may be supplied from a vaporizer to the plasma generation chamber, and a plasma is generated from the supplied vapor.

The vaporizer comprises a crucible in which a solid material is disposed, and a heater for increasing the crucible temperature. When the solid material in the crucible becomes equal to or higher than a sublimation temperature of the solid material, a vapor is generated from the solid material.

As described above, in order to continuously generate the plasma, a stable supply of a vapor from the vaporizer to the plasma generation chamber is required. In order to stably supply a vapor from the vaporizer, it is necessary to stably control the temperature of the solid material.

In a vaporizer, in order to control the temperature of the solid material, a structure in which the thermal conductivity of the support member for supporting the crucible is made lower than the thermal conductivity of the crucible is adopted to thermally separate the crucible from other members attached to the crucible.

With this configuration, the temperature of the crucible can be maintained at a high temperature during operation of the vaporizer, and stable temperature control can be achieved. However, when maintenance is to be performed on the ion source or the vaporizer for replacement of consumables or cleaning thereof, it is necessary to stop heating by the heater and remove the crucible. In the above configuration, since the crucible is thermally separated from other members, a long waiting time occurs until the temperature of the crucible cools down. As a countermeasure, a special cooling means for rapidly cooling the crucible temperature may be provided.

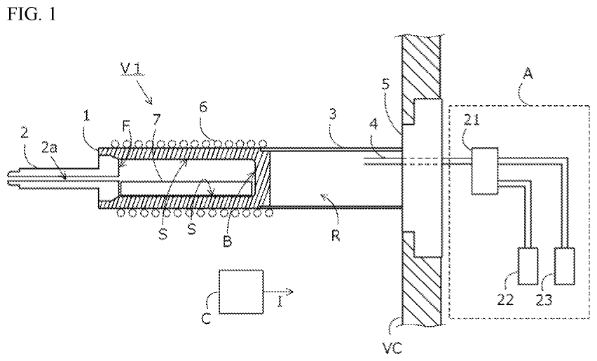

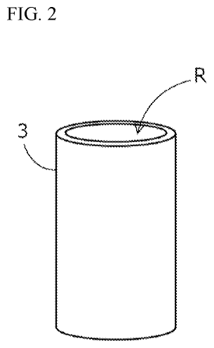

FIG. 1 is a schematic cross-sectional view of a vaporizer according to some embodiments. FIG. 2 is a perspective view of a support member, according to some embodiments. In a vaporizer V1, a solid material 7 is disposed inside a crucible 1. The solid material 7 may be, for example, aluminum trifluoride, indium iodide, indium chloride, antimony trifluoride, or the like. The solid material 7 has various forms such as a block, a pellet, or a powder.

An inner space of the crucible 1 comprises a front portion F, a side portion S and a bottom portion B. A heater 6 for heating the crucible 1 is provided on the outer periphery of the side portion S. The heater 6 may be, for example, a wire-shaped coil heater. By heating the crucible 1 (e.g., the heater 6 is turned on), the temperature of the solid material 7 becomes equal to or higher than the sublimation temperature thereof, and the solid material 7 is vaporized. A vapor of the solid material 7 is supplied to a plasma generation chamber (not shown) through a nozzle 2 provided at the front portion F of the crucible 1.

A support member 3 for supporting the crucible 1 on a vacuum partition wall 5 is, for example, an elongated cylindrical member shown in FIG. 2. Openings are formed at opposite ends of the support member 3. One end of the support member 3 is attached to the crucible 1, and the other end of the support member 3 is attached to the vacuum partition wall 5. An internal space R of the support member 3 is hermetically sealed except for the passage of the pipe 4 described later.

The vacuum partition wall 5 is, for example, a flange used for mounting the vaporizer V1 to a vacuum vessel of an ion source or a plasma source.

The vacuum partition wall 5 is attached to a wall of a vacuum vessel VC in which an ion source and a plasma source are disposed by a fixing member such as a bolt. In FIG. 1, a portion on the left side of the vacuum partition wall 5 is disposed inside the vacuum vessel, and a portion on the right side of the vacuum partition wall 5 is disposed outside the vacuum vessel.

The vacuum partition wall 5 may be used as a flange for attaching the ion source or the plasma source to the vacuum vessel VC. The vacuum partition wall 5 of the vaporizer V1 may be attached to a flange of the ion source or the plasma source, and the vaporizer V1 and the ion source or the vaporizer V1 and the plasma source may be collectively attached to the vacuum vessel VC.

A pipe 4 is introduced into the internal space R of the support member 3. In some embodiments, the pipe 4 may be in fluid communication with the internal space R. A three-way valve 21 is attached to the pipe 4. An air supply source 22 and a vacuum pump 23 are connected to the three-way valve 21. With this configuration, the pressure of the internal space R of the support member 3 can be switched through the pipe 4, for example, between a vacuum and atmospheric pressure. For example, the three-way valve 21 may be switched to connect the air supply source 22 to the internal space R through the pipe 4 to supply air to the internal space R through the pipe 4 to increase the pressure in the internal space R, and may be switched to connect the vacuum pump 23 to the internal space R through the pipe 4 to evacuate the air from the internal space R to decrease the pressure in the internal space R.

When an atmosphere in the internal space R of the support member 3 is the atmospheric pressure, the pressure in the internal space R of the support member 3 is set to 1 atm or is set to a pressure in the vicinity thereof. On the other hand, in the case where an atmosphere of the internal space R of the support member 3 is made to be a vacuum, an arbitrary pressure lower than atmospheric pressure is set.

The switching of the three-way valve 21 may be automatically controlled by the command signal I from the control device C according to the operating state of the vaporizer V1, or may be manually operated by an operator of the vaporizer, the ion source, or the plasma source.

In some embodiments, the control device C may include hardware control logic coded to produce the control signals I. In some embodiments, the controller may include at least on memory storing program code and at least one processor that accesses the at least one memory and executes the program code to generate the control signals I. Thus, the controller C may be configured control the three-way valve 21.

In the following description of a modification of the vaporizer V1, the three-way valve 21, the air supply source 22 and the vacuum pump 23 connected to the pipe 4 are shown as a state change assembly A. Further, the illustration of the vacuum vessel VC is omitted for simplification of the drawing.

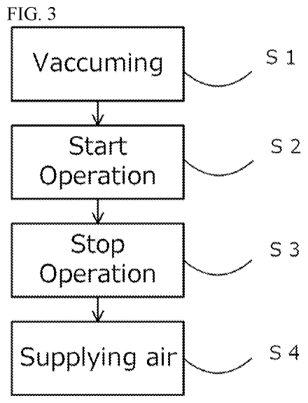

FIG. 3 is a flowchart showing an example of operation of the vaporizer V1, according to some embodiments. First, before the operation of the vaporizer V1, the internal space R of the support member 3 is evacuated by vacuuming (S1). Thereafter, the operation is started (S2). For example, the temperature of the crucible 1 is raised by the heater 6 (e.g., the heater 6 is turned on) to vaporize the solid material 7. At this time, since the internal space R of the support member 3 is a vacuum, heat transfer from the crucible 1 to the vacuum partition wall 5 side is reduced by the vacuum insulation effect. As a result, when the vaporizer V1 is operated and the solid material 7 is vaporized. The crucible 1 is thermally separated from the support 3, so that the crucible 1 is thermally stabilized.

When the crucible 1 is heated by the heater 6 (e.g., the heater 6 is turned on), the temperature of the crucible 1 may be raised in advance to a temperature at which the solid material 7 is not vaporized. For example, the temperature may be raised to a temperature just below the temperature at which the solid material 7 is vaporized. The time required to start the operation of the vaporizer V1 can be shortened by raising the temperature of the crucible 1 in advance to a temperature higher than the room temperature and lower than the temperature at which the solid material 7 is vaporized, rather than raising the temperature of the crucible 1 from the room temperature (about 25° C.) to a temperature at which the solid material 7 is vaporized.

Here, the operation of heating the crucible 1 in advance to a temperature at which the solid material 7 is not vaporized is referred to as preheating, and the operation of heating the crucible 1 to a temperature at which the solid material 7 is vaporized is referred to as final heating.

The preheating may be performed either during the process S1 or immediately before or after the process S1. However, in order to thermally stabilize the crucible 1 even in the preheating, it is advantageous to carry out the preheating of the crucible 1 after carrying out the vacuum drawing in the treatment S1.

Next, the operation of the vaporizer V1 is stopped (S3). For example, the operation of the vaporizer V1 may be stopped in order to perform maintenance on the vaporizer V1. Specifically, the heating of the crucible 1 by the heater 6 is stopped (e.g., the heater 6 is turned off).

Thereafter, air is supplied (S4). For example, air may be supplied to the internal space R of the support member 3 to make the internal space R of the support member 3 the atmospheric pressure, thereby promoting heat transfer from the crucible 1 to the vacuum partition wall 5. As a result, when the operation of the vaporizer V1 is stopped, the temperature of the vaporizer V1 can be rapidly reduced.

In some embodiments, in addition to or instead of air, an inert gas such as nitrogen gas or argon gas may be used for pressure adjustment in the internal space R of the support member 3. In some embodiments, the timing at which the process S4 is performed may be the same as the timing at which the process S3 is performed.

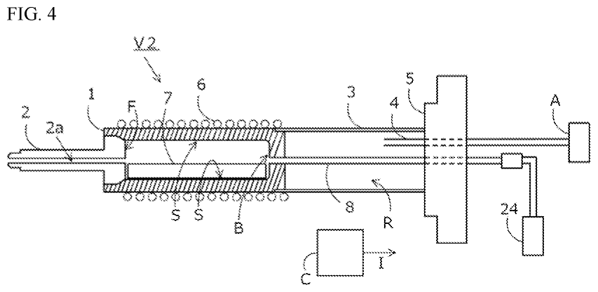

FIG. 4 is a schematic sectional view of a vaporizer V2, according to some embodiments. In FIG. 4 and other drawings to be described later, members having the same reference numerals as those of FIG. 1 are the same members, and detailed description thereof will be omitted for conciseness. The vaporizer V2 differs from the vaporizer V1 in the method of generating a vapor.

When a reactive gas is supplied to the crucible 1, the solid material 7 of the crucible 1 reacts with the reactive gas to produce a reaction product. The reaction product is vaporized by heating the crucible 1 with the heater 6. The vapor of the reaction product is supplied to a plasma generation chamber (not shown) through the opening 2a of the nozzle 2.

For example, the solid material 7 may be, for example, pure aluminum, aluminum nitride, or aluminum oxide, and the reactive gas may be, for example, chloride gas or hydrochloric acid gas. A reaction product produced by the reaction between the solid material 7 and the reactive gas is aluminum chloride.

The gas supply source 24 supplies a reactive gas such as chlorine gas or hydrochloric acid gas. A gas introduction pipe 8 is attached to the bottom B of the crucible 1, through which the reactive gas is supplied to the interior of the crucible 1.

The gas introduction pipe 8 is arranged in the internal space R of the support member 3 between the vacuum partition wall 5 and the crucible 1. With this configuration, the configuration of the vaporizer V2 is more compact than the configuration in which the gas introduction pipe 8 is disposed outside the support member 3.

Further, in some embodiments, in order to prevent gas leakage from the gas introduction pipe 8, the outside of the gas introduction pipe 8 may be covered with another pipe so as to have a double pipe structure.

In some embodiments, in the vaporizer V2, when the crucible 1 is heated by the heater 6, the internal space R of the support member 3 is evacuated. The internal space R may be evacuated by vacuuming. When the heating of the crucible 1 by the heater 6 is stopped in order to perform the maintenance of the vaporizer V2, the internal space R of the support 3 is made to be the atmospheric pressure to promote heat transfer from the crucible 1 to the vacuum partition wall 5.

In the vaporizer V2, no reaction product is produced inside the crucible 1 unless the reactive gas is supplied to the crucible 1. In a state in which there is no reaction product inside the crucible 1, even if the crucible 1 is heated, the vapor based on the reaction product is not generated.

In order to rapidly generate the vapor in the vaporizer V2, the temperature of the crucible 1 may be previously raised to the temperature of the final heating.

In some embodiments, the temperature of the vaporizer V2 may be set to the temperature of the preheating described for the vaporizer V1, and the crucible 1 may be heated by the heater 6 so that the temperature of the crucible 1 becomes the temperature of the final heating in accordance with the timing at which the reactive gas is supplied.

In order to easily perform control in the state change assembly A, it is desirable that the internal space R of the support member 3 is vacuum except when maintenance of the vaporizer V2 is performed, that is, when the heating of the crucible 1 by the heater 6 is stopped. The same can be said for other vaporizers.

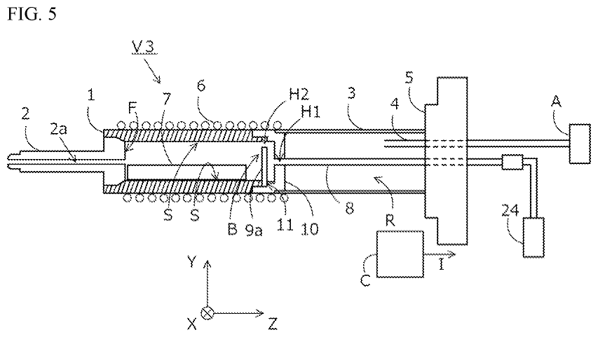

FIG. 5 is a schematic sectional view of a vaporizer V3, according to some embodiments. The difference from the vaporizer V2 shown in FIG. 4 is that the bottom portion B of the crucible 1 has a double bottom structure. The double bottom structure includes a first bottom lid 10 and a second bottom lid 9a as shown in FIG. 5. The main surfaces (surfaces on the XY plane shown in the figure) of the first bottom lid 10 and the second bottom lid 9a are arranged with a space therebetween in the Z direction, and heat transfer from the second bottom lid 9a to the first bottom lid 10 can be reduced by the space between the main surfaces.

By combining the double bottom structure shown in FIG. 5 with the configuration of FIG. 1 or 4, heat transfer from the crucible 1 to the vacuum partition wall 5 can be further reduced. Thus, the thermal stability of the crucible 1 is further improved.

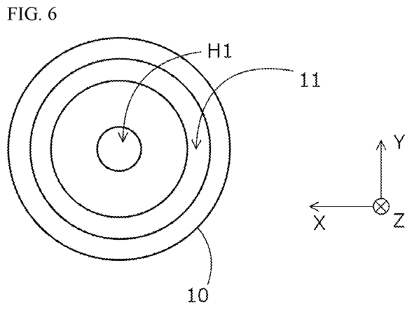

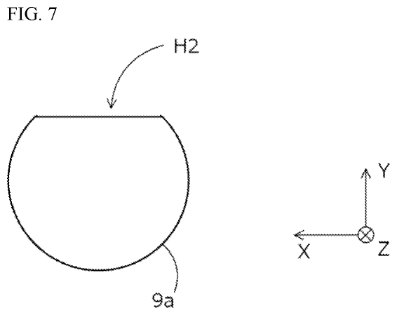

FIG. 6 illustrates an example of a first bottom lid, according to some embodiments, and FIG. 7 illustrates an example of a second bottom lid, according to some embodiments;

FIGS. 6 and 7 are plan views showing concrete structural examples of the first bottom lid 10 and the second bottom lid 9a. Here, it is assumed that the crucible 1 is a cylindrical member. However, the present disclosure is not limited thereto.

As shown in FIG. 6, the first bottom lid 10 may be a disc-shaped member in plan view and may have concentric circular steps. A first gas introduction port H1 through which the reactive gas passes is formed in the center of the first bottom lid 10. A second bottom lid 9a shown in FIG. 7 is disposed at the step portion 11 of the first bottom lid 10. The second bottom lid 9a is a member in which a notch is provided in a part of the disk, and the notch portion serves as a second gas introduction port H2 through which the reactive gas passes. In some embodiments, the second bottom lid 9a may serve, for example, as a deflector plate for the reactive gas.

The reactive gas passes through the first gas introduction port H1 and the second gas introduction port H2 and is introduced into the interior of the crucible 1 from the side portion S side of the crucible 1. Since the vicinity of the side portion S is heated by the heater 6, the temperature is relatively high and the vaporization of the reaction product is promoted. On the other hand, at the central position of the crucible 1 (near the center between the side portions S facing each other in the Y direction shown in FIG. 5), the temperature is lower than that in the vicinity of the side portions S, so that there is a concern that the vaporized reaction product may be fixed.

When the second gas introduction port H2 is located at the position of the first gas introduction port H1 in the Y direction, there is a concern that the reaction product adheres to the vicinity of the second gas introduction port H2 and hinders the introduction of the reactive gas into the crucible 1.

However, as shown in FIG. 5, since the position of the second gas introduction port H2 provided on the side of the crucible 1 is located near the side portion S which is eccentric from the center of the crucible 1, the above-mentioned problem can be solved. That is, the position of the first gas introduction port H1 may be placed at the center of the crucible 1 and the position of the second gas introduction port H2 may be displaced from the center of the crucible 1 such that the first gas introduction port H1 and the second gas introduction port H2 are not provide along a same axis.

The configurations of the first bottom lid 10 and the second bottom lid 9a shown in FIGS. 5 to 7 are merely examples, and various modifications are possible. For example, in some embodiments, the first bottom lid 10 may be a disc-like member having no step and fitted into the crucible 1. In some embodiments, the first bottom lid 10 may be sandwiched between the crucible 1 and the support member 3.

The notch of the second bottom lid 9a does not need to be linear as shown in FIG. 7, and in some embodiments, the notch may be curved. The notch portion shown in FIG. 7 may be formed not only on the upper side of the second bottom lid 9a as illustrated in FIG. 7 but may also be formed on the lower side of the second bottom lid 9a, so that the reactive gas can be supplied at a position eccentric from the center of the crucible 1 and the notch portion may be appropriately changed within a range that does not hinder the attachment of the second bottom lid 9a.

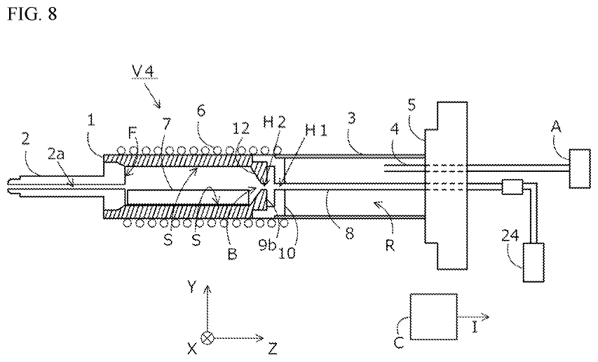

FIG. 8 illustrates an example of a vaporizer, according to some embodiments. As a modification of the vaporizer V3 having the crucible 1 having the double bottom structure shown in FIGS. 5 to 7, a vaporizer V4 shown in FIG. 8 may be adopted. In the vaporizer V4, a part of the crucible 1 is used as a second bottom lid 9b.

The second bottom lid 9b has an inclined portion 12 extending from the second gas introduction port H2 to the side portion S in a direction toward the front portion F of the crucible 1. That is, the inclined portion 12 slopes outward from the second gas introduction port H2 as a distance from the front portion F decreases. Since the solid material 7 is physically separated from the second gas inlet H2 by the inclined portion 12, the risk that the second gas inlet H2 is blocked by the sticking of vaporized reaction products can be reduced.

Instead of the inclined portion 12, in some embodiments, a stepwise portion may be provided to take the physical distance between the solid material 7 and the second gas inlet H2.

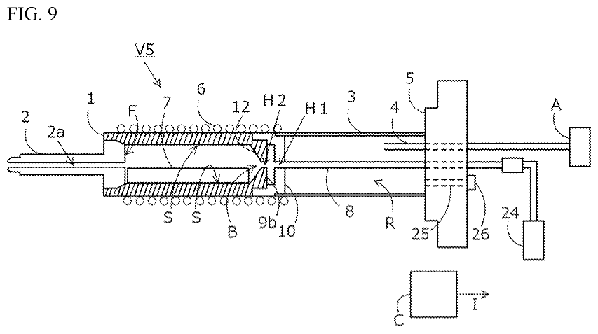

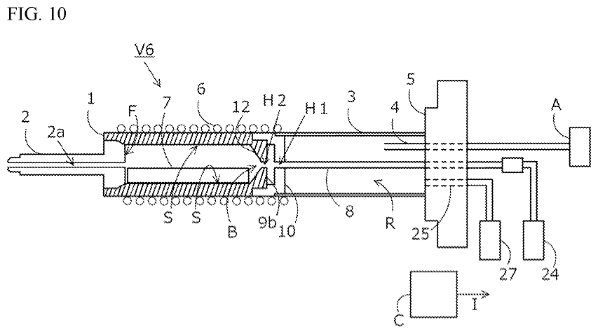

When maintenance of the vaporizer is performed, the temperature of the vaporizer can be efficiently lowered by adopting a configuration shown in FIGS. 9 and 10 in addition to the atmospheric pressure in the internal space R of the support member 3.

FIGS. 9-11 illustrate examples of a vaporizer, according to some embodiments. In a vaporizer V5 shown in FIG. 9 and a vaporizer V6 shown in FIG. 10, the vacuum partition wall 5 is provided with a passage 25 connected from outside of the vacuum vessel.

In the vaporizer V5 shown in FIG. 9, a knob 26 is provided at the end of the passage 25 outside the vacuum vessel. The knob 26 is a member for opening and closing the end of the passage 25. For example, in some embodiments, the knob 26 may be a member including a knurled bolt or a pipe and a valve for opening and closing the pipe.

When the internal space R of the support member 3 is at atmospheric pressure, the knob 26 opens the end of the passage 25. Thus, a gas warmed by the heat from the crucible 1 in the internal space R of the support member 3 can be released to outside the vacuum vessel through the end of the passage 25. As a result, the warm gas in the internal space R and the cold gas supplied from the pipe 4 are circulated, and the temperature of the crucible 1 can be efficiently lowered.

In some embodiments, the passage 25 may be always opened. In some embodiments, the opening and closing of the passage 25 by the knob 26 may be switched according to one or more of the supply time of the gas flowing through the pipe 4, the temperature of the crucible 1, the pressure fluctuation in the internal space R of the support member 3, or the like. In some embodiments, in addition to the temperature of the crucible 1, the temperature of the support member 3 and the internal space R of the support member 3 may be measured by a thermometer, and the knob 26 may be opened or closed according to the measured value. In some embodiments, the opening/closing operation of the knob 26 may be automatically controlled by using the control device C.

In the vaporizer V6 shown in FIG. 10, a pump 27 is provided instead of the knob 26. The gas warmed in the internal space R of the support member 3 may be discharged to the outside by using the pump 27.

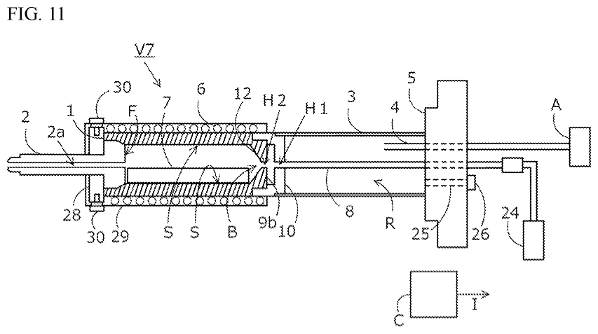

In order to raise the temperature of the crucible 1 efficiently, a shield 29 may be disposed around the heater 6. FIG. 11 is a schematic sectional view of a vaporizer V7 provided with a shield around the heater 6. In some embodiments, elements of the heater 6 may be encased in the shield 29.

The shield 29 shown is a tubular member. An opening is formed at an end portion of the shield 29 so that the nozzle 2 and the first bottom lid 10 can project into and out of the shield 29. The shield 29 is attached to a cap 28 disposed adjacent to a large-diameter portion of the nozzle 2 by a fastener 30 (e.g., a stud or pair of studs).

By using the shield 29 shown in FIG. 11, heat escaping to the outside of the crucible 1 can be shielded, so that the temperature of the crucible 1 can be raised efficiently. In addition, the heater 6 may be pressed against the crucible 1 by the shield 29 to enhance the adhesion of the heater 6 to the crucible 1.

As shown in FIG. 11, the number of shields 29 is not limited to one. One or more shields may be added to the outside of the shield 29 with a space. When a plurality of shields are provided, the thickness of each shield may be different. For example, in some embodiments, the thickness dimension of the shield 29 in contact with the heater 6 may be thin, compared to the thickness of the shield disposed outside the shield 29.

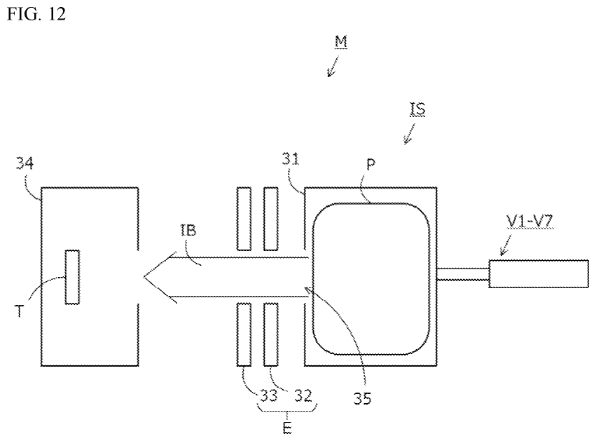

FIG. 12 is a schematic cross-sectional view showing a configuration example of an ion irradiation apparatus M, such as an ion implanter.

The ion irradiation apparatus M may include an ion source IS and a processing chamber 34. The ion source IS may include any of the vaporizers V1-V7 described above with respect to FIGS. 1-11. The vapor supplied from the vaporizer V1-V7 is introduced into a plasma generation chamber 31. The vapor introduced into the plasma generation chamber 31 is converted into plasma by ionized electrons emitted from a cathode (not shown) or microwaves generated by an antenna (not shown).

An ion extraction port 35 is formed on one surface of the plasma generation chamber 31. The plasma P generated in the plasma generation chamber 31 is extracted as an ion beam IB by an extraction electrode E through an ion extraction port 35 of the plasma generation chamber 31.

An extraction electrode E includes, for example, a suppression electrode 32 for suppressing the inflow of electrons into the plasma generation chamber 31 and a ground electrode 33 fixed to the ground potential. A predetermined voltage is applied to the plasma generation chamber 31 and the suppression electrode 32 by power supplies (not shown).

The target T arranged in the processing chamber 34 is irradiated with the ion beam IB extracted from the ion source IS, thereby processing the target T. The target T may be fixed at a specific position in the processing chamber 34, or may be moved in a direction crossing the ion beam IB.

Depending on the configuration of the ion beam irradiation apparatus M, various components such as a mass analysis electromagnet and an acceleration/deceleration tube may be disposed between the ion source IS and the processing chamber 34.

In the above-described embodiments, a material of the support member 3 may be a material having a lower thermal conductivity than the material constituting the crucible 1 so as to reduce heat transfer through the support member 3. For example, the crucible 1 may be made of isotropic graphite, and the support member 3 may be made of stainless steel.

If the crucible 1, the first bottom lid 10, and the second bottom lid 9a are made of the same material, a change in relative positions between the members can be reduced even if thermal expansion occurs in each member due to heating of the crucible 1 by the heater 6. It should be noted that the members do not necessarily need to be formed of the same material, and similar effects can be obtained by forming the crucible 1, the first bottom lid 10, and the second bottom lid 9a of a material having a small difference in thermal expansion coefficient.

Although the heater 6 is described above as a coil heater having a wire shape, a coil heater having a sheet shape may be used instead of the coil heater having a wire shape. In some embodiments, a panel heater with a flexible heating surface may also be used. In some embodiments, a plate heater arranged so as to surround the crucible 1 may be used. In some embodiments, each heater (i.e., the coil heater, the panel heater, and the plate heater) may be combined to form the heater 6.

Various methods such as fitting, screwing, welding and the like can be used for attaching the members. In addition, a mounting member may be newly prepared.

In order to improve the airtightness of the support member 3 with respect to the crucible 1 and the vacuum partition wall 5, welding may be used for attaching the support member 3. Further, the support member 3 is not limited to a single member, and may be a combination of a plurality of members.

Although the solid material 7 shown in the figure occupies half of the volume of the crucible 1, the solid material may be large enough to occupy the whole of the crucible 1. As the area of the solid material 7 in contact with the reactive gas becomes larger, the amount of the reaction product produced increases and the amount of the vapor produced in the crucible 1 also increases.

When the solid material 7 is increased in size, the shape and size of the solid material 7 are appropriately set so as not to block the supply path of the reactive gas supplied from the gas introduction pipe 8 to the crucible 1. For example, in the case where the solid material 7 is made as one large lump and the solid material 7 is made to be large enough to occupy the whole of the crucible 1, it is conceivable to form a plurality of holes in the solid material 7 in order to secure the flow path of the reactive gas.

The opening 2a of the nozzle 2 is not limited to a configuration in which the diameter is constant, but in some embodiments may be a configuration in which the diameters are stepwise different. For example, in consideration of clogging at the front portion F of the crucible 1, the diameter of the opening 2a on the front portion F side may be increased. Specifically, portions having different diameters of a large diameter and a small diameter are formed in the opening 2a of the nozzle 2 so that the front portion F side of the crucible 1 becomes larger in the direction in which the nozzle 2 extends. In some embodiments, the diameter of the opening 2a may be linearly or non-linearly reduced from the front portion F side of the crucible 1 toward the tip of the nozzle 2 in the direction in which the nozzle 2 extends.

The support member 3 need not be a cylindrical member, and in some embodiments may be any member as long as it is attached between the crucible 1 and the vacuum partition wall 5 to form an internal space R. For example, the support member 3 may be a rectangular member having the internal space R or a member having a U-shaped cross section.

It is to be understood that various embodiments have been described herein, but various changes and modifications may be made therein without departing from the spirit and scope thereof as set forth in appended claims.

What is claimed is:

1. An vaporizer comprising:
a crucible;
a heater that heats the crucible;
a support member that supports the crucible and includes an internal space in which a pressure in the internal space can be changed; and
a control device configured to increase the pressure of the internal space when the heating of the crucible by the heater is stopped, compared to the pressure when the crucible is heated by the heater.

2. The vaporizer according to claim 1, wherein the control device supplies a gas into the internal space, when the heating of the crucible by the heater is stopped.

3. The vaporizer according to claim 1, wherein the control device vacuums the internal space, when the crucible is heated by the heater.

4. The vaporizer according to claim 1, wherein the pressure in the internal space is substantially atmospheric pressure, when heating of the crucible is stopped by the heater.

5. The vaporizer according to claim 1, wherein the crucible further comprises:
a front portion that releases vapor; and
a bottom portion opposed to the front portion; and
wherein the bottom portion comprises a double bottom structure having a first bottom lid and a second bottom lid.

6. The vaporizer according to claim 1, wherein the crucible further comprises a gas introduction pipe that introduces a gas into the crucible,
wherein the gas introduction pipe is disposed in the internal space of the support member.

7. An ion source comprising:
the vaporizer according to claim 1, the vaporizer that outputs a vapor;
a plasma generation chamber that receives the vapor and generates a plasma based on the vapor; and
an extraction electrode that extracts an ion beam from the plasma.

8. An ion beam irradiation apparatus comprising:
the ion source according to claim 7; and
a processing chamber in which a target is disposed,
wherein the ion beam is irradiated into the processing chamber.

9. An operating method for a vaporizer comprising a crucible, a heater that heats the crucible, a support member that supports the crucible and includes an internal space in which a pressure in the internal space can be changed, the operating method comprising:
operating the vaporizer in which the pressure of the internal space is increased when heating of the crucible by the heater is stopped compared to the pressure when the crucible is heated by the heater.

10. A vaporizer comprising:
a crucible;
a heater configured to heat the crucible;
a support member that supports the crucible and includes an internal space; and
a control device configured to control to, when the heater is turned off, increase a pressure of the internal space with respect to the pressure of the internal space when the heater is turned on.

11. The vaporizer according to claim 10, wherein the control device is configured to control to, when the heater is turned on, decrease the pressure of the internal space with respect to the pressure when the heater is turned off.

12. The vaporizer according to claim 11, wherein, when the heater is turned on, the control device controls to create a vacuum in the internal space, and when the heater is turned off, the control device controls to create an atmospheric pressure in the internal space.

13. The vaporizer according to claim 10, further comprising:
a three-way valve;
a pipe connected to the three-way valve and to the internal space such that the three-way valve is in fluid communication with the internal space through the pipe;
a vacuum pump connected to the three-way valve; and
an air supply connected to the three-way valve,
wherein the control device is configured to control the three-way valve to connect the air supply to the internal space through the pipe when the heater is turned off and to connect the vacuum pump to the internal space through the pipe when the heater is turned on.

14. The vaporizer according to claim 10, wherein the crucible further comprises:
a front portion that releases vapor; and
a bottom portion opposed to the front portion,
wherein the bottom portion comprises a double bottom structure having a first bottom lid and a second bottom lid.

15. The vaporizer according to claim 10, wherein the heater heats the crucible to generate vapor from a solid material in the crucible.
